(19) United States
(12) Patent Application Publication
(10) Pub. No.: US 2008/0316361 A1
(43) Pub. Date: Dec. 25, 2008

(54) PICTURE SIGNAL PROCESSING DEVICE AND PICTURE SIGNAL PROCESSING METHOD

(76) Inventors: Yoshinori ITO, Shizuoka (JP); Tetsuji MORITA, Shizuoka (JP); Kosuke YAMAMOTO, Aichi (JP)

Correspondence Address: FROMMER LAWRENCE & HAUG LLP, 745 FIFTH AVENUE, NEW YORK, NY, 10151, US

(21) Appl. No.: 12/143,045

(22) Filed: Jun. 20, 2008

(30) Foreign Application Priority Data
Jun. 22, 2007 (JP) P2007-164884

(51) Int. Cl. H03M 1/12

(52) U.S. Cl. 348/572

(57) ABSTRACT

A picture signal processing device includes an A/D conversion unit configured to convert an input analog picture signal into a digital picture signal; an automatic image correction unit configured to correct the digital picture signal from the A/D conversion unit; a narrowing-down unit configured to narrow down possible formats of the analog picture signal based on horizontal and vertical signal frequencies of the analog picture signal, horizontal and vertical synchronizing signal polarities and vertical line count; and an identification unit configured to identify the format of the input analog picture signal from among a plurality of narrowed-down candidate signal formats.

### CROSS REFERENCES TO RELATED APPLICATIONS

The present invention contains subject matter related to Japanese Patent Application JP 2007-164884 filed with the Japan Patent Office on Jun. 22, 2007, the entire contents of which being incorporated herein by reference.

### BACKGROUND OF THE INVENTION

1. Field of the Invention

The present invention relates to a picture signal processing device and method, and more particularly to a picture signal processing device and method capable of identifying the format of an input picture signal.

2. Description of the Related Art

Today, a wide screen display is finding increasing application in electronic equipment with a display (display section) such as laptop and desktop personal computers (hereinafter abbreviated as PCs). On the other hand, a wide-screen-compatible RGB (R (red), G (green) and B (blue)) signal is becoming mainstream as a picture signal output from laptop PCs.

Incidentally, a concept such as aspect ratio exists in the case of a picture signal for video use. In contrast, such a concept is not widely recognized in the case of a picture signal for computer use. In a system operable to feed a PC signal from a laptop PC to a projector so as to display an image on the projector, therefore, the projector identifies the input picture signal format and displays the image according to the identification result.

Conventionally, the picture signal format has been identified by first detecting the horizontal and vertical frequencies of the input picture signal and the polarities of the synchronizing signals and then checking the detection result against the picture signal specification information (e.g., Japanese Patent Laid-Open No. 2000-305555).

### SUMMARY OF THE INVENTION

PC signals from computers such as laptop PCs are not compliant with any display standards (display formats). Many of these signals are very ambiguous, making it difficult for receiving equipment to accurately identify the format thereof. That is, it is difficult to find a signal format having exactly the same horizontal and vertical frequencies of the picture signal and polarities of the synchronizing signals in the picture signal specification information. For this reason, the horizontal and vertical signal frequencies have a margin to allow easy identification of the picture signal format.

However, PC signals from computers such as laptop PCs are not compliant with any of the display standards as described above. As a result, some of these picture signals are of different formats although having almost the same horizontal and vertical frequencies or synchronizing signal polarities. Therefore, when such a picture signal is received, the format thereof may be erroneously identified because of the margins of the horizontal and vertical signal frequencies.

On the other hand, when a PC signal from a computer such as laptop PC is fed to receiving equipment (e.g., projector) via a cable, the picture signal may change, for example, in frequency while being transmitted over the cable. Such a change is caused by factors such as line resistance, which is determined by the cable length, and parasitic capacitance. Also in this case, the signal format may be erroneously identified because of the margins of the horizontal and vertical signal frequencies.

In light of the foregoing, it is desirable to provide a picture signal processing device and method capable of identifying any format of an input picture signal from external equipment so as to produce an image output at a proper aspect ratio.

To achieve the aforementioned desire, the present invention provides a picture signal processing device. The picture signal processing device includes an A/D conversion unit adapted to convert an input analog picture signal into a digital picture signal. The same device further includes an automatic image correction unit adapted to correct the digital picture signal from the A/D conversion unit. First, the same device narrows down possible formats of the analog picture signal based on the horizontal and vertical frequencies of the same signal, the polarities of the horizontal and vertical synchronizing signals and the vertical line count. Then, the same device identifies the format of the analog picture signal from among a plurality of narrowed-down candidates for the signal format.

To identify the signal format, the picture signal processing device determines parameters of the A/D conversion unit for the candidate which has produced the best quality of all the candidates. The same device operates the A/D conversion unit with the determined parameters to calculate the horizontal resolution of the analog picture signal. Then, the same device identifies the format of the analog picture signal from among the plurality of candidates based on the horizontal image size, which is one of the parameters, and the horizontal resolution.

The present invention identifies the format of an input picture signal from among a plurality of candidates eventually based on the horizontal image size and horizontal resolution. This makes it possible to identify a signal format which differs slightly in horizontal resolution from the display standard. As a result, any format of an input picture signal can be identified so that the input picture signal is displayed at a proper aspect ratio.

### BRIEF DESCRIPTION OF THE DRAWINGS

FIG. 1 is a block diagram illustrating a system configuration example of a projector having a picture signal processing device according to the present invention;

FIG. 2 is a flowchart illustrating an example of process steps for identifying optimal signal conditions to find a match;

FIG. 3 is a flowchart illustrating an example of process steps for identifying the format of an input RGB signal from among a plurality of signal formats having the same vertical line count;

FIG. 4 is a timing waveform diagram illustrating the relationship between a horizontal image size HTotal, a horizontal blanking interval HBlk and the horizontal resolution of an input picture signal;

FIG. 5 is a timing waveform diagram illustrating the timing relationship between a horizontal synchronizing signal HSync, picture data from an A/D converter and a sampling clock of the A/D converter;

FIG. 6 is a view illustrating an example of an OSD menu adapted to change the aspect ratio; and

FIG. 7 is a conceptual diagram showing how the aspect ratio is changed.

### DETAILED DESCRIPTION OF THE PREFERRED EMBODIMENT

The preferred embodiment of the present invention will be described below with reference to the accompanying drawings.

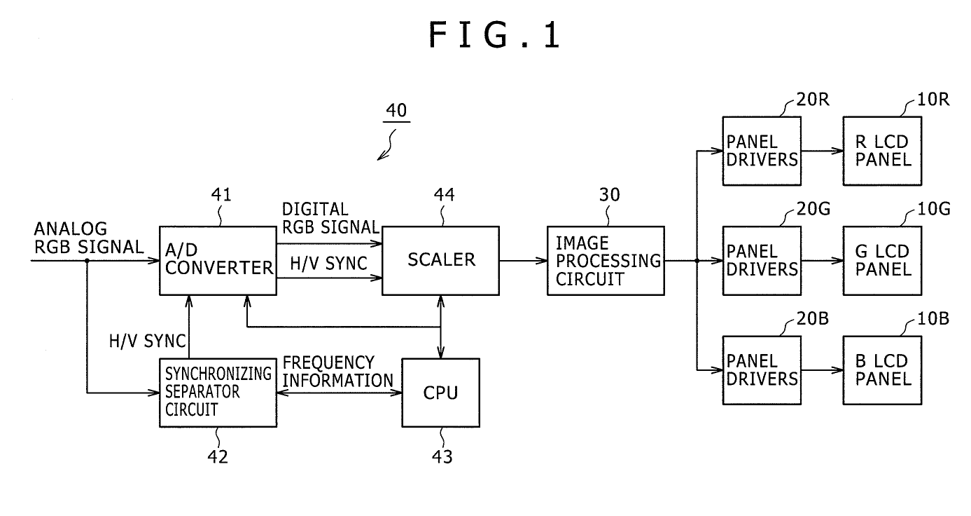

FIG. 1 is a block diagram illustrating a system configuration example of a projector having a picture signal processing device according to the present invention.

As illustrated in FIG. 1, the present projection system includes R, G and B LCD (liquid crystal) panels 10R, 10G and 10B, panel drivers 20R, 20G and 20B adapted to respectively drive the LCD panels 10R, 10G and 10B. The same system further includes an image processing circuit 30 adapted to perform various types of image processing and a picture signal processing device 40 to which the present invention applies.

The picture signal processing device 40 includes an A/D converter 41, synchronizing separator circuit 42, CPU 43 and scaler 44.

The A/D converter 41 converts an input analog RGB signal into a digital RGB signal in synchronism with horizontal and vertical synchronizing signals HSync and VSync separated from the analog RGB signal by the synchronizing separator circuit 42.

The synchronizing separator circuit 42 can not only separate the horizontal and vertical synchronizing signals HSync and VSync from the input analog RGB signal but also identify horizontal and vertical frequencies fH and fV of the same signal.

The CPU 43 obtains the horizontal and vertical signal frequencies fH and fV and polarities of the horizontal and vertical synchronizing signals from the synchronizing separator circuit 42. The CPU 43 controls the processes performed by the A/D converter 41 and scaler 44 by communicating therewith based on the horizontal and vertical signal frequencies fH and fV and polarities of the horizontal and vertical synchronizing signals obtained from the synchronizing separator circuit 42. This control of the processes is a characteristic feature of the present invention, and a detailed description thereof will be given later.

The scaler 44 scales the image based on the input RGB signal, including scaling down, cutting and zooming the image. Further, the scaler 44 can automatically correct the screen size and position (shift) to eliminate unsharpness of the image resulting from dot shift and ghosting (this function will be hereinafter referred to as the “automatic image correction function”). The automatic image correction function is a well-known art.

It should be noted that although the CPU 43 and scaler 44 are shown as separate blocks, they may be configured on a single chip depending on the model.

The picture signal processing device 40 according to the present invention configured as described above controls the processes of the A/D converter 41 and scaler 44 under the control of the CPU 43. As a result, even if the input RGB signal is not compliant with any display standards (display formats), the picture signal processing device 40 performs the process steps adapted to identify optimal signal conditions to find a match. A specific example thereof will be described below.

### EXAMPLE

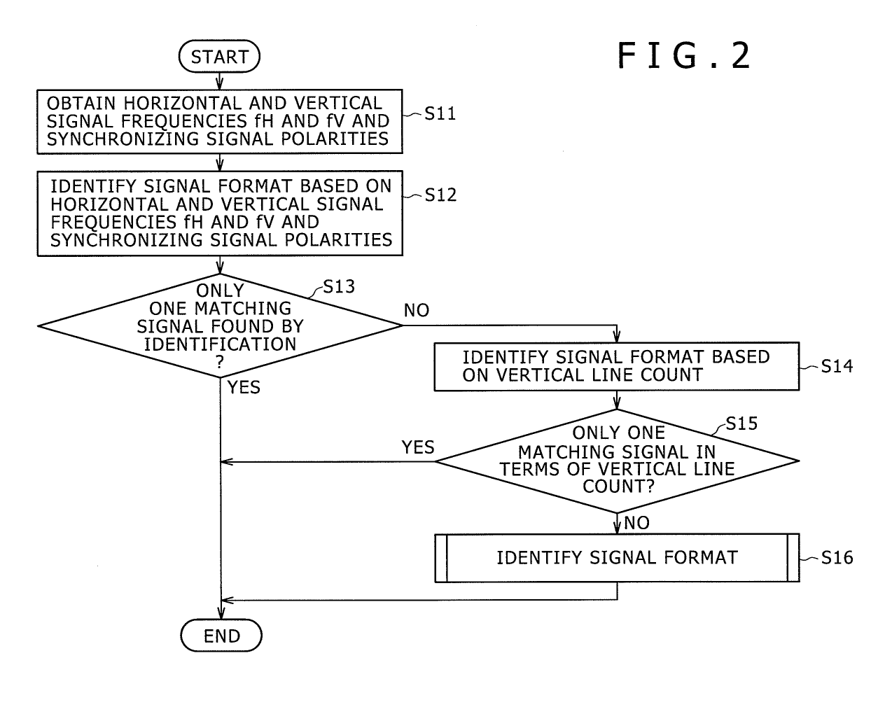

FIG. 2 is a flowchart illustrating an example of process steps adapted to identify optimal signal conditions to find a match. These process steps are performed under the control of the CPU 43.

We assume that before the process steps are carried out, all picture signal formats (specification information), including not only those compliant with one of the display standards such as XGA, WXGA and UXGA but also others not compliant with any standards, are stored in the storage area of the scaler 44 as a signal information table.

Here, the term “picture signal format (specification information)” refers to information such as resolution (horizontal pixel count by vertical pixel count), horizontal and vertical signal frequencies fH and fV, and horizontal image size HTotal. The horizontal image size HTotal will be described later.

In the flowchart of FIG. 2, the CPU 43 obtains the horizontal and vertical signal frequencies fH and fV and polarities of the horizontal and vertical synchronizing signals from the synchronizing separator circuit 42 (step S11) first. Next, the CPU 43 checks the obtained signal frequencies fH and fV and synchronizing signal polarities against those of various picture signal formats to find a match and identify the format of input RGB signal (step S12).

As described earlier, PC signals from computers such as laptop PCs are not compliant with any display standards, and many of these signals are very ambiguous. This makes it difficult to find a signal format which has exactly the same horizontal and vertical signal frequencies fH and fV and horizontal and vertical synchronizing signal polarities.

For this reason, the horizontal and vertical signal frequencies have a margin to allow easy identification of the picture signal format. This margin of the horizontal and vertical signal frequencies makes it more likely that a plurality of picture signal formats will be identified to match the input RGB signal in the signal format identification process in step S12.

Following the signal format identification process, the CPU 43 determines whether there is only one match as a result of the identification in step S12 (step S13). If so, the CPU 43 terminates the process steps by determining that the matching picture signal format is the format of the input RGB signal.

On the other hand, if there are a plurality of matches found by the identification in step S12, the CPU 43 checks the vertical line count against those of various picture signal formats stored in the storage area of the scaler 44 as a signal information table to identify the format of the input RGB signal (step S14). The vertical line count can be found based on the horizontal synchronizing signal. The vertical line count corresponds to the vertical pixel count.

Next, the CPU 43 determines whether there is only one match in terms of vertical line count (step S15). If so, the CPU 43 terminates the process steps by determining that the matching picture signal format is the format of the input RGB signal.

On the other hand, if there are a plurality of matches in terms of vertical line count, the CPU 43 proceeds to the process of identifying the input picture signal format by narrowing down the plurality of matches to one (step S16). The specific process in this step S16 is a characteristic feature of the present invention, and a detailed description thereof will be given later.

### (Signal Format Identification Process)

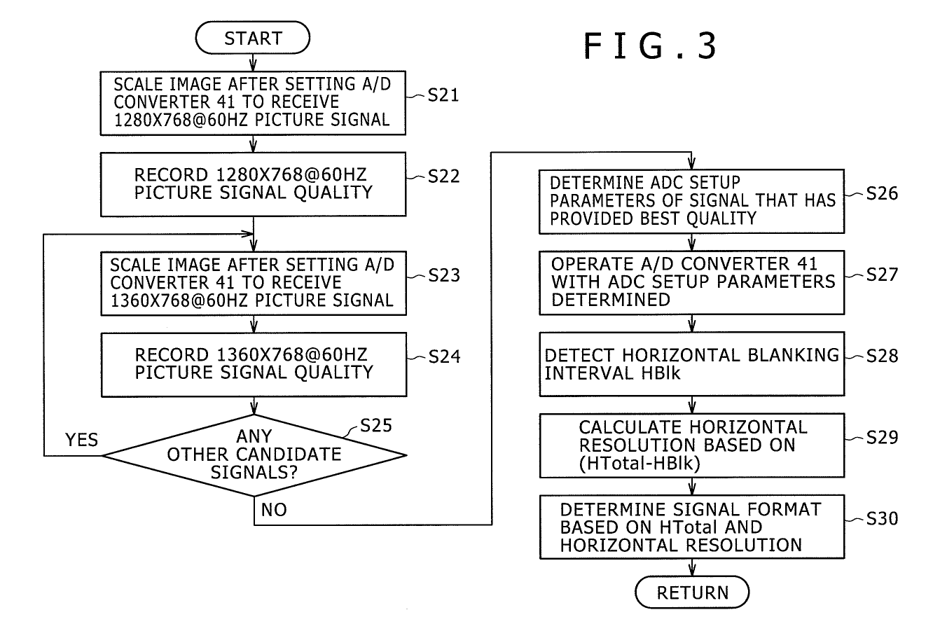

FIG. 3 is a flowchart illustrating an example of process steps for identifying the input picture signal format by narrowing down a plurality of signal formats having the same vertical line count to one.

Here, a description will be given by citing, as an example, a case in which an input picture signal in WXGA format (resolution: 1280×768, fH=47.78 kHz, fV=59.87 Hz, HTotal=1664) is discriminated from another picture signal having closely similar fH and fV (resolution: 1360×768, fH=47.72 kHz, fV=59.80 Hz, HTotal=1776).

These two signal formats correspond to the plurality of signal formats which have been narrowed down as candidates for the input RGB signal format in the process steps up to step S15 in the flowchart of FIG. 2. That is, the two signal formats WXGA1280×768@60 Hz and WXGA1360×768@60 Hz have closely similar horizontal and vertical signal frequencies fH and fV. That is, the signal frequencies fH and fV of the former are 47.78 kHz and 59.87 Hz, whereas those of the latter 47.72 kHz and 59.80 Hz. Moreover, the two signals have the same vertical line count, which is 768.

The CPU 43 cannot narrow down the candidates for the input RGB signal format to one in the process steps up to step S15 in the flowchart of FIG. 2. As a result, the CPU 43 first sets the sampling clock frequency of the A/D converter 41 to receive the WXGA1280×768@60 Hz picture signal. Then, the CPU 43 uses the scaler 44 to perform the automatic image correction described earlier.

Next, the CPU 43 loads and records the quality of the WXGA1280×768@60 Hz picture signal which is detected by a digital signal input block (not shown) provided in the input stage of the scaler 44 (step S22). The picture signal quality will be described later.

The CPU 43 sets the sampling clock frequency of the A/D converter 41 to receive the WXGA1360×768@60 Hz picture signal which is another candidate and uses the scaler 44 to perform the automatic image correction (step S23). Next, the CPU 43 loads and records the quality of the WXGA1360×768@60 Hz picture signal which is detected by the digital signal input block of the scaler 44 (step S24).

Then, the CPU 43 determines whether there is any other signal which may be considered as a candidate (step S25). In the present example, a case is described as an example in which the signal formats are narrowed down to two candidates. However, if any other signals may be candidates, the CPU 43 will return to step S23 to repeat steps S23 and S24 for the other candidates.

When the automatic image correction of all the candidate signals by the scaler 44 is complete, the CPU 43 compares all the candidate signals in terms of image correction quality. The CPU 43 determines the ADC setup of the A/D converter 41 for the candidate signal which has provided the best quality by searching the signal information table (step S26). Among possible ADC parameters are the horizontal image size HTotal and sampling clock phase.

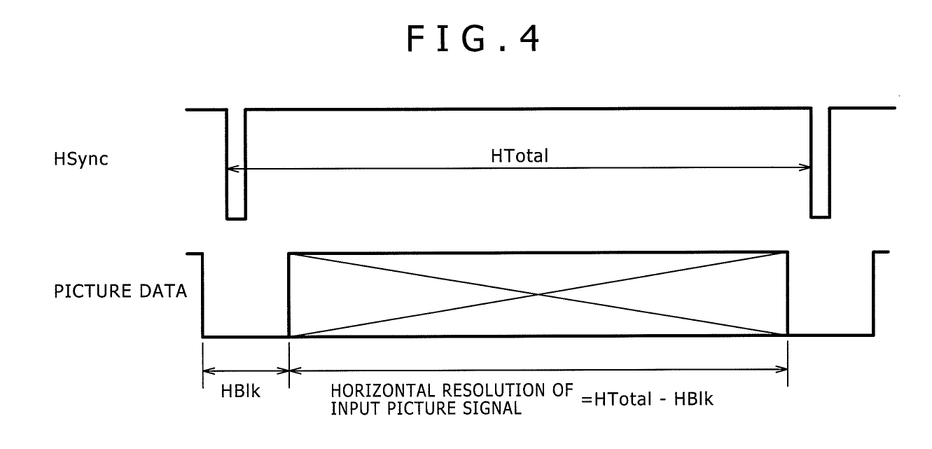

Next, the CPU 43 operates the A/D converter 41 with the ADC setup parameters determined in step S26 (step S27). Then, the CPU 43 detects a horizontal blanking interval HBlk of the picture signal using the digital signal input block provided in the input stage of the scaler 44 (step S28). Next, the CPU 43 calculates the horizontal resolution of the picture signal (picture signal period) as illustrated in FIG. 4 based on the difference between the horizontal image size HTotal, which is one of the ADC setup parameters, and the horizontal blanking interval HBlk (HTotal−HBlk) (step S29). The horizontal image size HTotal is a horizontal period.

Next, based on the horizontal image size HTotal and the horizontal resolution, the CPU 43 eventually narrows down the plurality of candidates to a single optimal signal and identifies the format thereof as the format of the input picture signal (step S30).

This identification result is fed back to the scaler 44. In response, the scaler 44 sets the aspect ratio so that the image is displayed at an aspect ratio associated with the format of the input picture signal.

As is clear from the descriptions given above, the CPU 43 includes a narrowing-down unit and an identification unit. The narrowing-down unit narrows down possible formats of an analog picture signal based on the horizontal and vertical signal frequencies fH and fV of the analog picture signal, horizontal and vertical synchronizing signal polarities and vertical line count. The identification unit identifies the format of the input analog picture signal from among a plurality of narrowed-down candidates.

### (ADC Setup)

A description will now be given of the ADC setup of the A/D converter 41 determined in step S26. The ADC setup parameters are the horizontal image size HTotal and sampling clock phase.

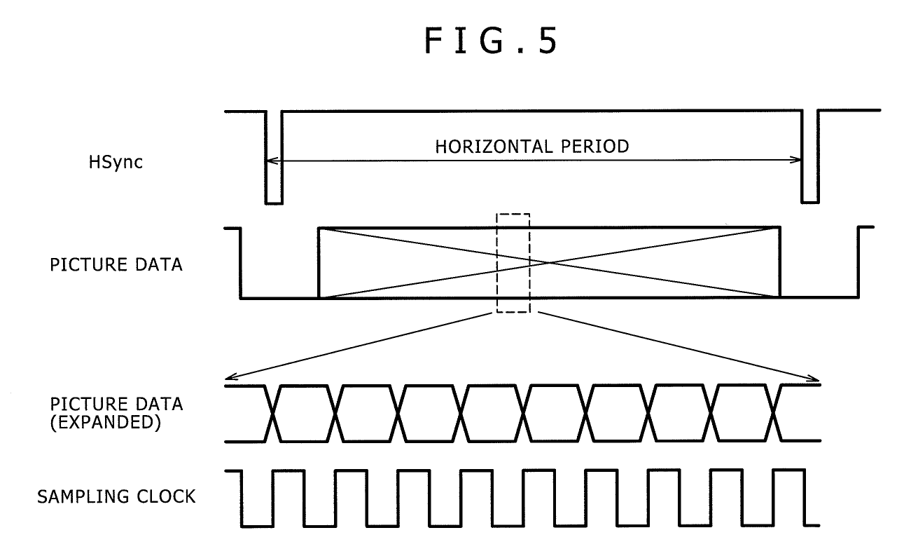

FIG. 5 illustrates the timing relationship between the horizontal synchronizing signal HSync, the picture data from the A/D converter 41 and the sampling clock of the same converter.

The horizontal image size (horizontal width) HTotal is associated with the horizontal period and refers to the A/D conversion sampling rate (sampling clock rate) for the horizontal period. The sampling clock period is determined by the horizontal image size HTotal.

Therefore, if not set properly, the horizontal image size HTotal will cause the A/D conversion sampling rate to become inconsistent with the picture data resolution.

The sampling clock phase refers to the phase relative to the picture data. If the sampling clock is out of phase with the picture data, the A/D conversion by the A/D converter 41 cannot produce a proper digital value.

### (Picture Signal Quality)

Next, the picture signal quality will be described in a more specific manner. This quality is detected by the digital signal input block provided in the input stage of the scaler 44 as described earlier.

If the ADC setup parameters to which the A/D converter 41 is set, namely, the horizontal image size HTotal and sampling clock phase, are not appropriate for the input analog picture signal, the A/D conversion sampling will not be performed properly. This results in a sampled digital value different from the correct one. Conversely, if the ADC setup parameters are set properly, there will be no difference between the sampled digital value and correct one.

On the other hand, when viewed along the time axis, the sampled digital data looks as if it has a jitter as compared to the analog input data. The digital value produced by the A/D conversion is fed to the scaler 44 as capture data. The digital signal input block provided in the input stage of the scaler 44 makes it possible to examine the quality of the digital picture data.

For example, if digital picture data is received which is the same, when viewed along the time axis, as the picture data associated with the sampling clock frequency to which the A/D converter 41 is set, there is no difference between the data at a given time and that at a time slightly later. On the other hand, if received digital picture data is different when viewed along the time axis, it is probable that this elapse of time has produced a difference in data. Therefore, the smaller the difference, the better the quality.

From the above, it can be concluded as follows. That is, the candidate signal that has provided the best quality in step S26 has the smallest difference in data over time. This signal contains the picture data that is almost identical to that associated with the sampling clock frequency to which the A/D converter 41 is set in step S21 or S23.

In the above example, a case was described in which an input picture signal in WXGA format (resolution: 1280×768, fH=47.78 kHz, fV=59.87 Hz, HTotal=1664) is discriminated from another picture signal having closely similar fH and fv (resolution: 1360×768, fH=47.72 kHz, fv=59.80 Hz, HTotal=1776). However, the above case is merely an example, and the present invention is not limited thereto.

As described above, the picture signal processing device according to the present invention narrows down possible formats to a plurality of formats from among those registered in advance in the signal information table. The same device does so based on the horizontal and vertical frequencies of the same signal, the polarities of the horizontal and vertical synchronizing signals and the vertical line count. The same device determines the ADC setup parameters for the signal which has provided the best quality of all the candidate signals. The same device operates the A/D converter 41 with the determined parameters to calculate the horizontal resolution of the input picture signal. The same device eventually identifies the input picture signal format from among the plurality of candidates based on the horizontal image size HTotal and horizontal resolution, thus allowing for discrimination between signal formats slightly different in display standard and horizontal resolution.

This makes it possible to identify any format of an input picture signal from computers such as laptop PCs, including those not compliant with any display standards and others which have deviated from one of the standards due to frequency variation during transmission caused, for example, by the cable. As a result, any non-standard signals can be faithfully reproduced (displayed) while maintaining the aspect ratio.

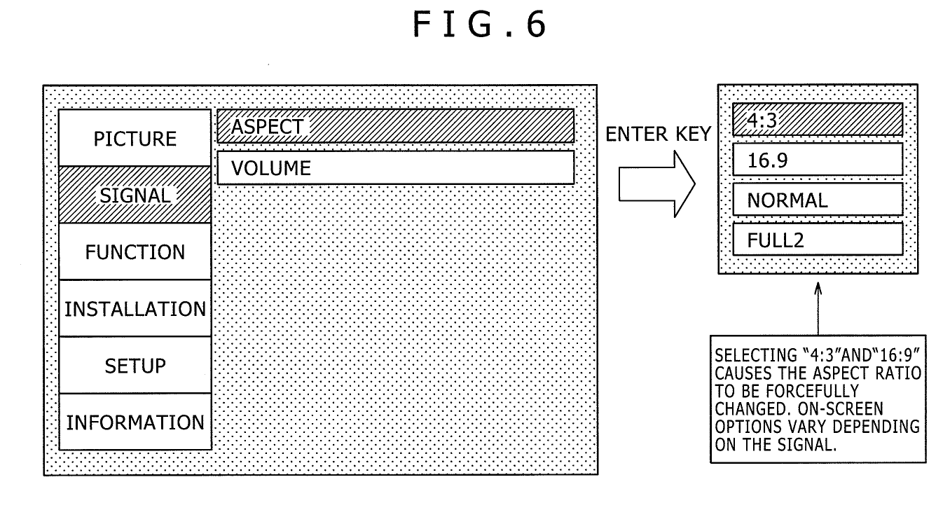

It should be noted that the picture signal processing device according to the present invention has a mode adapted to forcefully change the aspect ratio in the OSD (On Screen Display) menu as illustrated in FIG. 6. This mode is provided assuming that the same device may not be able to identify the signal format even by means of the above signal format identification sequence.

More specifically, the user selects “Aspect” from the Signal menu. From the options shown on screen, the user selects “4:3” or “16:9” with the Enter key. This will forcefully change the aspect ratio. It should be noted that on-screen options vary depending on the signal.

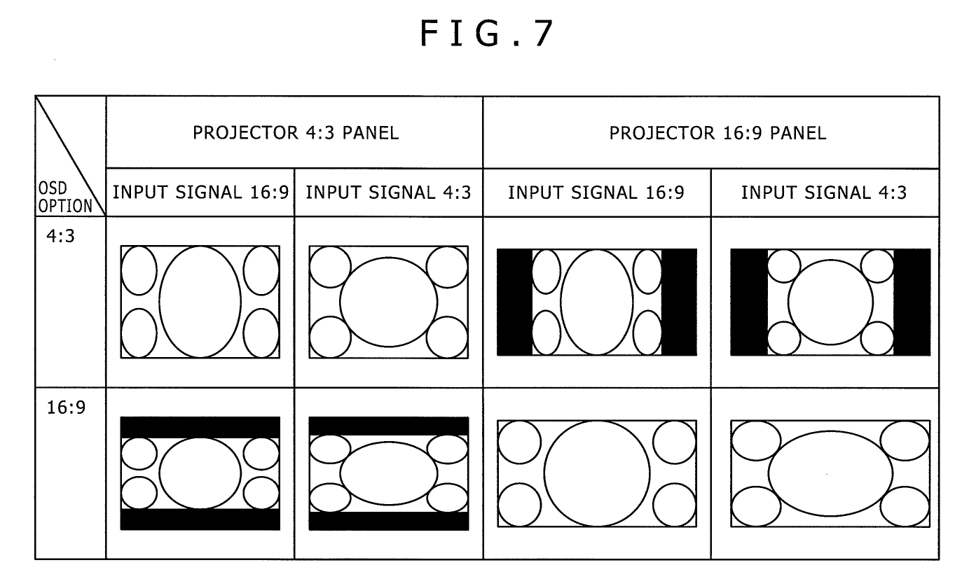

FIG. 7 is a conceptual diagram showing how the aspect ratio is changed. We assume that a picture signal having a 16:9 aspect ratio is received when the projector's panel aspect ratio is 4:3. In this case, selecting the OSD option of “4:3” displays a vertically long image. Selecting the OSD option of “16:9” displays a normal image with a black bar at the top and bottom.

Next, we assume that a picture signal having a 4:3 aspect ratio is received when the projector's panel aspect ratio is 4:3. In this case, selecting the OSD option of “4:3” displays a normal image. Selecting the OSD option of “16:9” displays a horizontally long image with a black bar at the top and bottom.

Next, we assume that a picture signal having a 16:9 aspect ratio is received when the projector's panel aspect ratio is 16:9. In this case, selecting the OSD option of “4:3” displays a vertically long image with a black bar on the right and left. Selecting the OSD option of “16:9” displays a normal image.

Next, we assume that a picture signal having a 4:3 aspect ratio is received when the projector's panel aspect ratio is 16:9. In this case, selecting the OSD option of “4:3” displays a normal image with a black bar on the right and left. Selecting the OSD option of “16:9” displays a horizontally long image.

As described above, a mode adapted to forcefully change the aspect ratio in the OSD menu makes it possible to forcefully treat a signal having, for example, a 4:3 aspect ratio as a wide-screen signal through switching by the user. Conversely, the signal aspect ratio can be forcefully changed from 16:9 to 4:3. As a result, the aspect ratio can be maintained even in the event of a signal input whose format cannot be identified by the above signal format identification sequence.

A description has been given by citing as an example a case in which the present invention is applied to a projector in the above embodiment. However, the present invention is not limited in its application to a projector. Instead, the present invention may be applied, for example, to a television system.

It should be understood by those skilled in the art that various modifications, combinations, sub-combinations and alterations may occur depending on design requirements and other factor in so far as they are within the scope of the appended claims or the equivalents thereof.

What is claimed is:

1. A picture signal processing device comprising:
analog-to-digital conversion means adapted to convert an input analog picture signal into a digital picture signal;
automatic image correction means adapted to correct the digital picture signal from the analog-to-digital conversion means;
narrowing-down means adapted to narrow down possible formats of the analog picture signal based on horizontal and vertical signal frequencies of the analog picture signal, horizontal and vertical synchronizing signal polarities and vertical line count; and
identification means adapted to identify the format of the input analog picture signal from among a plurality of narrowed-down candidate signal formats, wherein
the identification means determine parameters of the analog-to-digital conversion means for the signal format which has produced the best quality of all the candidate signal formats, operate the analog-to-digital conversion means with the determined parameters to calculate a horizontal resolution of the analog picture signal, and identify the format of the analog picture signal from among the plurality of candidate signal formats based on the horizontal image size, which is one of the parameters, and the horizontal resolution.

2. The picture signal processing device of claim 1, wherein
the identification means set the sampling clock frequency of the analog-to-digital conversion means to receive each of the plurality of signals in candidate formats, perform the automatic image correction using the automatic image correction means to detect the quality of each of the plurality of signals in candidate formats, and identify the signal which has produced the best quality by comparison in terms of quality.

3. The picture signal processing device of claim 1, wherein
the parameters of the analog-to-digital conversion means are an analog-to-digital conversion sampling rate for a horizontal period and sampling clock phase.

4. The picture signal processing device of claim 3, wherein
the identification means detect a horizontal blanking interval of the analog picture signal and calculate the horizontal resolution based on the difference between the horizontal period and horizontal blanking interval during operation of the analog-to-digital conversion means.

5. The picture signal processing device of claim 1 further comprising
a display screen adapted to display a menu which allows various functions to be set up, wherein
a mode is available as a menu option of the display screen to forcefully change the aspect ratio of the analog picture signal.

6. A picture signal processing method of a picture signal processing device,
the picture signal processing device including
analog-to-digital conversion means adapted to convert an input analog picture signal into a digital picture signal, and
automatic image correction means adapted to correct the digital picture signal output from the analog-to-digital conversion means,
the picture signal processing method comprising the steps of:
narrowing down possible formats of the analog picture signal based on horizontal and vertical signal frequencies of the analog picture signal, horizontal and vertical synchronizing signal polarities and vertical line count; and
identifying the format of the input analog picture signal from among a plurality of narrowed-down candidate signal formats, wherein
the identification step determines parameters of the analog-to-digital conversion means for the candidate signal format which has produced the best quality of all the candidate signal formats, operates the analog-to-digital conversion means with the determined parameters to calculate a horizontal resolution of the analog picture signal, and identifies the format of the analog picture signal from among the plurality of candidate signal formats based on the horizontal image size, which is one of the parameters, and the horizontal resolution.

7. A picture signal processing device comprising:
an analog-to-digital conversion unit configured to convert an input analog picture signal into a digital picture signal;
an automatic image correction unit configured to correct the digital picture signal from the analog-to-digital conversion unit;
a narrowing-down unit configured to narrow down possible formats of the analog picture signal based on horizontal and vertical signal frequencies of the analog picture signal, horizontal and vertical synchronizing signal polarities and vertical line count; and
an identification unit configured to identify the format of the input analog picture signal from among a plurality of narrowed-down candidate signal formats, wherein
the identification unit determine parameters of the analog-to-digital conversion unit for the signal format which has produced the best quality of all the candidate signal formats, operate the analog-to-digital conversion unit with the determined parameters to calculate a horizontal resolution of the analog picture signal, and identify the format of the analog picture signal from among the plurality of candidate signal formats based on the horizontal image size, which is one of the parameters, and the horizontal resolution.
